(19) United States
(12) Patent Application Publication
(10) Pub. No.: US 2025/0234459 A1
(43) Pub. Date: Jul. 17, 2025

(54) CHIP-TO-CHIP INTERCONNECT DESIGN

(71) Applicant: NVIDIA CORPORATION, Santa Clara, CA (US)

(72) Inventors: Zikuan QIU, Shenzhen (CN); Yu Cheng CHANG, Shenzhen (CN); Rong FANG, Shenzhen (CN); Ruixuan LI, Shenzhen (CN); Jianhua DING, Shenzhen (CN); Jie ZHOU, Shenzhen (CN)

(73) Assignee: NVIDIA CORPORATION, Santa Clara, CA (US)

(21) Appl. No.: 18/582,902

(22) Filed: Feb. 21, 2024

Related U.S. Application Data
(63) Continuation of application No. PCT/CN2024/071956, filed on Jan. 12, 2024.

(51) Int. Cl. H05K 1/14; H05K 1/18

(52) U.S. Cl. CPC H05K 1/145; H05K 1/142; H05K 1/181

(57) ABSTRACT

Electronic modules and methods for manufacturing electronic modules are described herein. Some embodiments of the present invention may be directed to an electronic module that includes a main printed circuit board (PCB) having a first surface, a first chip substrate disposed on the first surface, and a second chip substrate disposed on the first surface. The electronic module may include an intermediate PCB supported by the main PCB, where at least a portion of the intermediate PCB is disposed between the first chip substrate and the second chip substrate. The intermediate PCB may electrically connect the first chip substrate to the second chip substrate. For example, the intermediate PCB may include pins extending substantially parallel to the first surface, and the first chip substrate and the second chip substrate may include contacts configured to electrically connect to the pins of the intermediate PCB.

### CROSS-REFERENCE TO RELATED APPLICATION

The present application claims the benefit of International Application No. PCT/CN2024/071956 for a “Chip-to-Chip Interconnect Design” filed on Jan. 12, 2024, which is hereby incorporated by reference in its entirety.

### FIELD OF THE INVENTION

The present invention relates designs for providing a chip-to-chip interconnections.

### BACKGROUND

Electronic modules may include more than one processor chip (e.g., a processing unit mounted on a processor substrate) mechanically and electrically connected to a main printed circuit board (PCB). The processor chips may be electrically connected to each other via various metal layers within the main PCB.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to an electronic module including a main printed circuit board (PCB), a first chip substrate, a second chip substrate, and an intermediate PCB. The main PCB may have a first surface, and the first chip substrate and the second chip substrate may be disposed on the first surface of the main PCB. The intermediate PCB may be supported by the main PCB, and at least a portion of the intermediate PCB may be disposed between the first chip substrate and the second chip substrate. The intermediate PCB may electrically connect the first chip substrate to the second chip substrate.

In some embodiments, the intermediate PCB may include first pins extending substantially parallel to the first surface of the main PCB from the intermediate PCB toward the first chip substrate and second pins extending substantially parallel to the first surface of the main PCB from the intermediate PCB toward the second chip substrate. The first pins and the second pins may be configured to electrically connect to the first chip substrate and the second chip substrate, respectively.

Additionally, or alternatively, the first chip substrate may include first contacts oriented toward the intermediate PCB, where each first contact is configured to electrically connect to a corresponding first pin of the first pins, and the second chip substrate may include second contacts oriented toward the intermediate PCB, where each second contact is configured to electrically connect to a corresponding second pin of the second pins. In some embodiments, the first contacts may be disposed on a first chip surface of the first chip substrate that is substantially perpendicular to the first surface of the main PCB, and the second contacts may be disposed on a second chip surface of the second chip substrate that is substantially perpendicular to the first surface of the main PCB. Additionally, or alternatively, the first chip substrate may define a first socket including the first contacts, and the second chip substrate may define a second socket including the second contacts.

In some embodiments, the first surface of the main PCB may define a first processor socket and a second processor socket. The first chip substrate may include a first processor socket interface configured to electrically connect to the first processor socket, and the first contacts and the first processor socket interface may be on different surfaces of the first chip substrate. The second chip substrate may include a second processor socket interface configured to electrically connect to the second processor socket, and the second contacts and the second processor socket interface may be on different surfaces of the second chip substrate.

In some embodiments, the intermediate PCB may include first test points configured to allow testing of first electrical connections between the first pins and the intermediate PCB, where each first test point corresponds to a first pin of the first pins. Additionally, or alternatively, the intermediate PCB may include second test points configured to allow testing of second electrical connections between the second pins and the intermediate PCB, where each second test point corresponds to a second pin of the second pins.

In some embodiments, the intermediate PCB may include a first portion disposed between a first side of the first chip substrate and a first side of the second chip substrate and a second portion extending along a second side of one of the first chip substrate or the second chip substrate. The first portion may be electrically connected to one of the first chip substrate or the second chip substrate, and the second portion may be electrically connected to the second side of the one of the first chip substrate or the second chip substrate.

In some embodiments, the intermediate PCB may include a third portion extending along a third side of the one of the first chip substrate or the second chip substrate. The first portion may be electrically connected to one of the first chip substrate or the second chip substrate, and the third portion may be electrically connected to the third side of the one of the first chip substrate or the second chip substrate.

In some embodiments, the intermediate PCB may include a first attachment feature configured to secure a first end of the intermediate PCB to the main PCB and a second attachment feature configured to secure a second end of the intermediate PCB to the main PCB. Additionally, or alternatively, the first attachment feature may include a first opening extending through the intermediate PCB, where the main PCB defines a first corresponding opening extending from the first surface to a second surface of the main PCB. In some embodiments, the second attachment feature may include a second opening extending through the intermediate PCB, where the main PCB defines a second corresponding opening extending from the first surface to a second surface of the main PCB. Additionally, or alternatively, the first attachment feature and the first corresponding opening of the main PCB may be configured to receive a first attachment member therethrough, and the second attachment feature and the second corresponding opening of the main PCB may be configured to receive a second attachment member therethrough. In some embodiments, the first attachment member may include a first bolt, and the second attachment member may include a second bolt.

In some embodiments, the first chip substrate may include a first processing unit, and the second chip substrate may include a second processing unit. Additionally, or alternatively, in an operable configuration, the first processing unit and the second processing unit may be configured to communicate with each other via an electrical connection provided by the intermediate PCB. For example, in an operable configuration, the first processing unit and the second processing unit may communicate with each other only via the electrical connection provided by the intermediate PCB, the first chip substrate, and the second chip substrate.

In another aspect, the present invention is directed to a method of manufacturing an electronic module. The method may include positioning a first chip substrate in a first socket on a first surface of a main printed circuit board (PCB) and positioning a second chip substrate in a second socket on the first surface of the main PCB. The method may include supporting an intermediate PCB at least partially between the first socket and the second socket, where the intermediate PCB is configured to electrically connect the first chip substrate and the second chip substrate.

In some embodiments, the method may include electrically connecting the intermediate PCB with the first chip substrate and the second chip substrate via pins of the intermediate PCB and sockets of the first chip substrate and the second chip substrate, respectively.

In some embodiments, the method may include testing an electrical connection via one or more test points on the intermediate PCB.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1A is a perspective view of an electronic module, in accordance with an embodiment of the invention;

FIG. 1B is a cross-sectional view of the electronic module of FIG. 1A, in accordance with an embodiment of the invention;

FIG. 1C is a perspective view of a portion of the electronic module of FIG. 1A, in accordance with an embodiment of the invention;

FIG. 1D is an elevation view of sides of the chip substrates of the electronic module of FIG. 1A, in accordance with an embodiment of the invention;

FIG. 1E is a partially exploded, elevation view of a portion of the electronic module of FIG. 1A, in accordance with an embodiment of the invention;

FIG. 1F is a perspective view of a first surface of the main PCB of the electronic module of FIG. 1A, in accordance with an embodiment of the invention;

FIG. 1G is a bottom view of the chip substrates of the electronic module of FIG. 1A, in accordance with an embodiment of the invention;

FIG. 2A is a schematic overhead view of an electronic module, in accordance with an embodiment of the invention;

FIG. 2B is a schematic overhead view of an electronic module, in accordance with an embodiment of the invention; and

FIG. 3 is a flowchart illustrating a method of manufacturing an electronic module, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Like numbers refer to like elements throughout. No element, act, or instruction used herein should be construed as critical or essential unless explicitly described as such.

As noted above, electronic modules may include more than one processor chip (e.g., a processing unit mounted on a processor substrate) mechanically and electrically connected to a main printed circuit board (PCB). The processor chips may be electrically connected to each other via various metal layers within the main PCB. For example, the processor chips may communicate with each other using conventional chip-to-chip (C2C) connectors. However, conventional C2C connectors require significant physical area on the main PCB, which limits the positioning and use of other elements (e.g., passive components, memory, integrated circuits, and/or the like) on the main PCB. Furthermore, the additional layers within the main PCB increase production cost and use C2C high-speed signals, which are incompatible with other power circuits in the main PCB. Also, the other power circuits may interfere with and create noise in such C2C high-speed signals, which causes a reduction in transmission rates.

Some embodiments of the present invention are directed to a design for providing a C2C interconnection using pins and an intermediate printed circuit board (PCB) positioned between chip substrates and above the main PCB. The chip substrates may include processor socket interfaces for connecting to the main PCB. However, the chip substrates may also include sockets for receiving the pins of the intermediate PCB, where the sockets are positioned on vertical surfaces of the chip substrates (i.e., side surfaces, surfaces perpendicular to the surface of the main PCB, etc.).

The intermediate PCB may include test points (e.g., on an upper surface) for testing the electrical connections (e.g., to determine signal quality) provided by the intermediate PCB between the two chips and/or the connectivity between the pins of the intermediate PCB and the intermediate PCB. In some embodiments, the intermediate PCB may be L-shaped or U-shaped, such that it electrically connects to one of the chip surfaces that is not proximate the other chip. For example, as described in greater detail below, each chip may have a socket on its right, vertical surface, and the intermediate PCB may be U-shaped, such that one portion of the intermediate PCB is positioned between the chips, another portion wraps around one chip, and yet another portion electrically connects to the right surface of the one chip. To secure the intermediate PCB to the main PCB, bolts may extend through the main PCB, and the intermediate PCB may be secured via nuts at the corners of the intermediate PCB.

In this way, the intermediate PCB may provide a direct chip-to-chip interconnection. Such a chip-to-chip interconnection may conserve package size, reduce pin count on the chips, reduce routing density, and reduce the required number of PCB layers in the main PCB. Such a chip-to-chip interconnection may also allow for lower pin densities and increased spacing between traces and vias, which reduces noise coupling and permits higher operating speeds. Additionally, such a chip-to-chip interconnection may allow for the addition of pins for expanding the functions of the chips. Furthermore, the chip-to-chip interconnection may be fully shielded from outside interference, which may permit increased transmission rates.

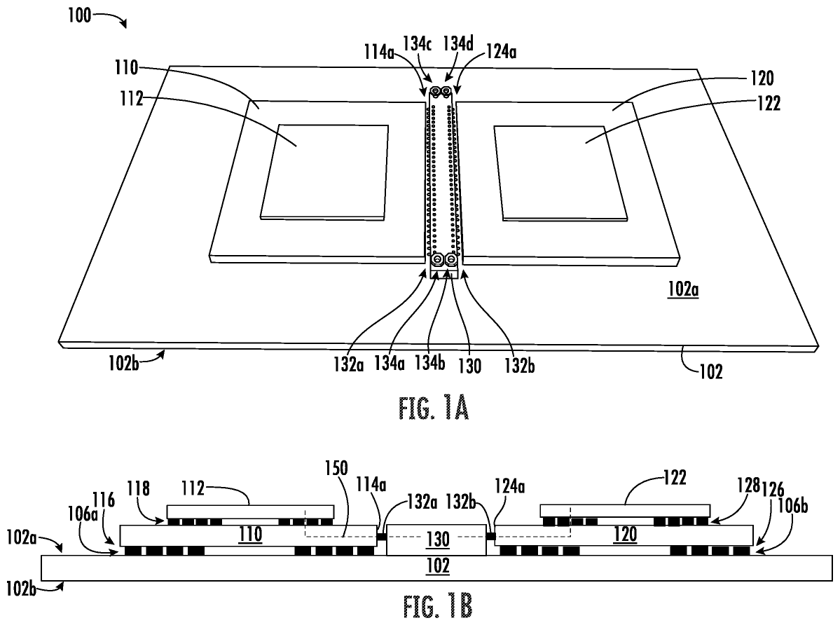

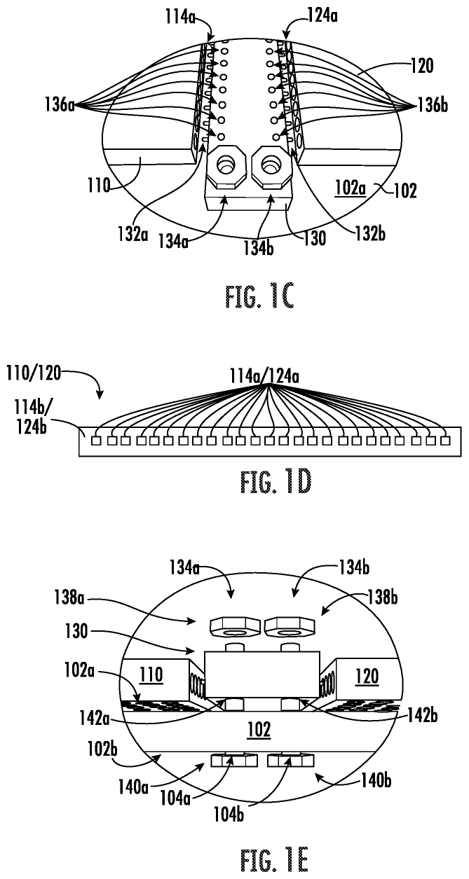

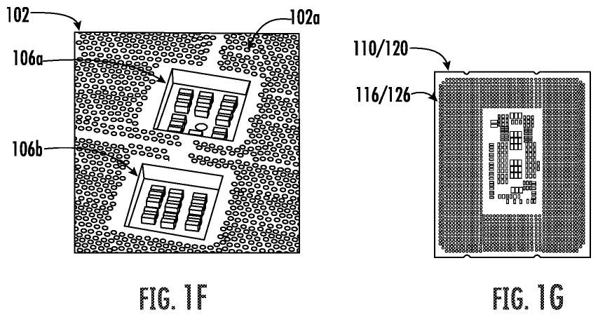

FIGS. 1A and 1B are perspective and cross-sectional views, respectively, of an electronic module 100, in accordance with an embodiment of the invention. As shown in FIGS. 1A and 1B, the electronic module 100 may include a main PCB 102, a first chip substrate 110, a second chip substrate 120, and an intermediate PCB 130.

As also shown in FIGS. 1A and 1B, the main PCB 102 may have a rectangular, planar shape and have a first surface 102a (e.g., a top surface) and a second surface 102b (e.g., a bottom surface). The first chip substrate 110, the second chip substrate 120, and the intermediate PCB 130 may be disposed on the first surface 102a as shown in FIGS. 1A and 1B. In some embodiments, at least a portion of the intermediate PCB 130 may be disposed between the first chip substrate 110 and the second chip substrate 120 as also shown in FIGS. 1A and 1B.

The first chip substrate 110 may include a first processing unit 112 (e.g., a central processing unit, a graphics processing unit, and/or the like), first contacts 114a, a first processor socket interface 116 (shown in FIG. 1B), and first processing unit interface 118 (shown in FIG. 1B) configured for receiving the first processing unit 112. Similarly, the second chip substrate 120 may include a second processing unit 122 (e.g., a central processing unit, a graphics processing unit, and/or the like), second contacts 124a, a second processor socket interface 126 (shown in FIG. 1B), and second processing unit interface 128 (shown in FIG. 1B) configured for receiving the second processing unit 122. In some embodiments, and as described further herein with respect to FIGS. 1C and 1D, the first contacts 114a and the second contacts 124a may be oriented toward the intermediate PCB 130 when the first chip substrate 110, the second chip substrate 120, and the intermediate PCB 130 are disposed on the first surface 102a of the main PCB 102.

As shown in FIGS. 1A and 1B, the intermediate PCB 130 may include first pins 132a extending substantially parallel to the first surface 102a of the main PCB 102 from the intermediate PCB 130 toward the first chip substrate 110. In some embodiments, the intermediate PCB 130 may be a substrate having a shape configured such that at least a portion of the intermediate PCB 130 may be positioned between the first chip substrate 110 and the second chip substrate 120. Additionally, or alternatively, the intermediate PCB 130 may have a first surface (e.g., a top surface) and a second surface (e.g., a bottom surface), where the second surface is configured to be oriented toward the first surface 102a of the main PCB 102.

As also shown in FIGS. 1A and 1B, the intermediate PCB 130 may include second pins 132b extending substantially parallel to the first surface 102a of the main PCB 102 from the intermediate PCB 130 toward the second chip substrate 120. In some embodiments, and as described further herein with respect to FIGS. 1C and 1D, the first pins 132a and the second pins 132b may be configured to electrically connect to the first chip substrate 110 and the second chip substrate 120, respectively. For example, each of the first pins 132a may be electrically connected to a corresponding second pin of the second pins 132b via one or more metal layers within the intermediate PCB 130 such that an electrical signal may be transmitted from the first chip substrate 110 through the intermediate PCB 130 to the second chip substrate 120.

As shown in FIG. 1A, the intermediate PCB 130 may include attachment features 134a-134d configured to secure ends of the intermediate PCB 130 to the main PCB 102. For example, and as shown in FIG. 1A, each of the attachment features 134a-134d may be configured to secure a respective corner of the intermediate PCB 130 to the main PCB 102. Additional aspects of the attachment features 134a-134d are described further herein with respect to FIG. 1E.

As shown in FIG. 1B, the intermediate PCB 130 may electrically connect the first chip substrate 110 to the second chip substrate 120 via a chip-to-chip interconnection 150. In particular, each of the first contacts 114a may be configured to electrically connect to a corresponding first pin of the first pins 132a, and each of the second contacts 124a may be configured to electrically connect to a corresponding second pin of the second pins 132b. In this way, the intermediate PCB 130 may provide the chip-to-chip interconnection 150 such that a signal from the first processing unit 112 may be transmitted through the first processing unit interface 118, the first chip substrate 110, one of the first contacts 114a, a corresponding first pin of the first pins 132a, the intermediate PCB 130, one of the second pins 132b, a corresponding second contact of the second contacts 124a, the second chip substrate 120, and the second processing unit interface 128 to the second processing unit 122 and vice versa.

In some embodiments, and as shown in FIG. 1B, the first surface 102a of the main PCB 102 may define a first processor socket 106a and a second processor socket 106b. As shown in FIG. 1B, the first processor socket interface 116 of the first chip substrate 110 may be configured to electrically and/or mechanically connect to the first processor socket 106a, and the second processor socket interface 126 of the second chip substrate 120 may be configured to electrically and/or mechanically connect to the second processor socket 106b. In some embodiments, and as shown in FIG. 1B, the first contacts 114a and the first processor socket interface 116 may be on different surfaces of the first chip substrate 110. Similarly, and as shown in FIG. 1B, the second contacts 124a and the second processor socket interface 126 may be on different surfaces of the second chip substrate 120. Additional aspects of the first processor socket 106a, the second processor socket 106b, the first processor socket interface 116, and the second processor socket interface 126 are described further herein with respect to FIGS. 1F and 1G.

FIG. 1C is a perspective view of a portion of the electronic module 100 of FIG. 1A, in accordance with an embodiment of the invention. As shown in FIG. 1C, the intermediate PCB 130 may include first test points 136a and second test points 136b on a surface (e.g., an upper surface) of the intermediate PCB 130 that are accessible when the intermediate PCB 130 is disposed on the first surface 102a of the main PCB 102 between the first chip substrate 110 and the second chip substrate 120.

In some embodiments, the first test points 136a may be configured to allow testing of electrical connections between the first pins 132a and the intermediate PCB 130 (e.g., one or more metal layers within the intermediate PCB 130). For example, each first test point of the first test points 136a may correspond to a first pin of the first pins 132a. Additionally, or alternatively, the first test points 136a may be configured to allow testing of signal quality between the first chip substrate 110 and the second chip substrate 120.

In some embodiments, the second test points 136b may be configured to allow testing of electrical connections between the second pins 132b and the intermediate PCB 130 (e.g., one or more metal layers within the intermediate PCB 130). For example, each second test point of the second test points 136b may correspond to a second pin of the second pins 132b. Additionally, or alternatively, the second test points 136b may be configured to allow testing of signal quality between the first chip substrate 110 and the second chip substrate 120.

FIG. 1D is an elevation view of sides of the first chip substrate 110 and the second chip substrate 120 of the electronic module 100 of FIG. 1A, in accordance with an embodiment of the invention. In particular, FIG. 1D shows the sides of the first chip substrate 110 and the second chip substrate 120 that are oriented toward the intermediate PCB 130. In this regard, the first contacts 114a and the second contacts 124a are oriented toward the intermediate PCB 130. In some embodiments, and as shown in FIGS. 1C and 1D, the first contacts 114a may be disposed on a first chip surface of the first chip substrate 110 that is substantially perpendicular to the first surface 102a of the main PCB 102. Similarly, the second contacts 124a may be disposed on a second chip surface of the second chip substrate 120 that is substantially perpendicular to the first surface 102a of the main PCB 102.

As shown in FIG. 1D, each of the first chip substrate 110 and the second chip substrate 120 may define a first socket 114b and a second socket 124b, respectively, where the first socket 114b includes the first contacts 114a, and the second socket 124b includes the second contacts 124a. In some embodiments, each of the first contacts 114a may be configured to electrically connect to a corresponding first pin of the first pins 132a, and each of the second contacts 124a may be configured to electrically connect to a corresponding second pin of the second pins 132b.

In this regard, when the first chip substrate 110 and the second chip substrate 120 are positioned proximate the sides of the intermediate PCB 130 (e.g., in an operable configuration), the first pins 132a may be in electrical communication with the first contacts 114a, and the second pins 132b may be in electrical communication with the second contacts 124a. For example, the first pins 132a may be positioned in the first socket 114b, and the second pins 132b may be positioned in the second socket 124b.

As shown in FIGS. 1C and 1D, the first pins 132a and the first contacts 114a are arranged in a single row of equally spaced elements, and the second pins 132b and the second contacts 124a are similarly arranged in a single row of equally spaced elements. As will be appreciated by one of ordinary skill in the art in view of the present disclosure, the first pins 132a, the first contacts 114a, the second pins 132b, and/or the second contacts 124a may be arranged in different arrangements in some embodiments. For example, the first pins 132a, the first contacts 114a, the second pins 132b, and/or the second contacts 124a may be arranged in multiple rows of equally spaced elements, a single row of unequally spaced elements, and/or other configurations.

As will be appreciated by one of ordinary skill in the art in view of the present disclosure, FIGS. 1A, 1C, and 1D depict the first chip substrate 110, the second chip substrate 120, and the intermediate PCB 130 in positions before the first pins 132a are positioned in the first socket 114b, and before the second pins 132b are positioned in the second socket 124b. Thus, as depicted in FIGS. 1A, 1C, and 1D, the first pins 132a are not contacting the first contacts 114a, and the second pins 132b are not contacting the second contacts 124a. However, when the first chip substrate 110, the second chip substrate 120, and the intermediate PCB 130 are in an operable configuration on the main PCB 102, the first pins 132a contact the first contacts 114a, and the second pins 132b contact the second contacts 124a.

FIG. 1E is a partially exploded, elevation view of a portion of the electronic module 100 of FIG. 1A, in accordance with an embodiment of the invention. As shown in FIG. 1E, the attachment feature 134a may include a nut 138a, a bolt 140a, and an opening 142a in the intermediate PCB 130, and the attachment feature 134b may include a nut 138b, a bolt 140b, and an opening 142b in the intermediate PCB 130. Although not shown in FIG. 1E, each of the attachment features 134c, 134d shown in FIG. 1A may be similar to the attachment features 134a, 134b shown and described herein with respect to FIG. 1E.

In FIG. 1E, the nuts 138a, 138b are depicted above the surface of the intermediate PCB 130 before being secured to the bolts 140a, 140b, respectively. Similarly, the first chip substrate 110, the second chip substrate 120, and the intermediate PCB 130 are depicted above the first surface 102a of the main PCB 102 before being secured thereto.

As shown in FIG. 1E, the main PCB 102 may define openings 104a, 104b extending from the first surface 102a to the second surface 102b of the main PCB 102. In some embodiments, the opening 142a and the opening 104a may be configured to receive an attachment member therethrough, and the opening 142b and the opening 104b may be configured to receive another attachment member therethrough. As depicted in FIG. 1E, the attachment members include the nuts 138a, 138b and the bolts 140a, 140b. As will be appreciated by one of ordinary skill in the art in view of the present disclosure, the attachment members may include additional components and/or different components or features (e.g., washers, threads, adhesives, screws, clamps, and/or the like).

FIG. 1F is a perspective view of the first surface 102a of the main PCB 102 of the electronic module 100 of FIG. 1A, in accordance with an embodiment of the invention. As shown in FIG. 1F, the first surface 102a of the main PCB 102 may define the first processor socket 106a and the second processor socket 106b. In some embodiments, the first processor socket 106a may be configured to electrically and/or mechanically connect to the first processor socket interface 116 of the first chip substrate 110. Additionally, or alternatively, the second processor socket 106b may be configured to electrically and/or mechanically connect to the second processor socket interface 126 of the second chip substrate 120. For example, the first processor socket 106a and the second processor socket 106b may include electrical components, such as contacts, pins, and/or the like, for providing electrical connections and mechanical components, such as openings, protrusions, edges, and/or the like, for mechanically receiving and/or supporting the first chip substrate 110 and the second chip substrate 120, respectively.

FIGS. 1B and 1F depict the first processor socket 106a and the second processor socket 106b as being substantially similar to each other. As will be appreciated by one of ordinary skill in the art in view of the present disclosure, the first processor socket 106a and the second processor socket 106b may be substantially different from each other in some embodiments. For example, the first processor socket 106a and the second processor socket 106b may be configured to receive different types of chip substrates, differently shaped chip substrates, differently sized chip substrates, and/or the like, which may result in the first processor socket 106a and the second processor socket 106b having different mechanical and/or electrical characteristics as compared to each other.

FIG. 1G is a bottom view of the first chip substrate 110 and the second chip substrate 120 of the electronic module 100 of FIG. 1A, in accordance with an embodiment of the invention. As shown in FIG. 1G, surfaces (e.g., bottom surfaces) of the first chip substrate 110 and the second chip substrate 120 oriented toward the first surface 102a of the main PCB 102 in an operable configuration may include the first processor socket interface 116 and the second processor socket interface 126, respectively. In some embodiments, the first processor socket interface 116 of the first chip substrate 110 may be configured to electrically and/or mechanically connect to the first processor socket 106a, and the second processor socket interface 126 of the second chip substrate 120 may be configured to electrically and/or mechanically connect to the second processor socket 106b. For example, the first processor socket interface 116 and the second processor socket interface 126 may include electrical components, such as contacts, pins, and/or the like, for providing electrical connections and mechanical components, such as openings, protrusions, edges, and/or the like, for mechanically receiving and/or interfacing with the first processor socket 106a and the second processor socket 106b, respectively.

FIGS. 1B and 1G depict the first processor socket interface 116 and the second processor socket interface 126 as being substantially similar to each other. As will be appreciated by one of ordinary skill in the art in view of the present disclosure, the first processor socket interface 116 and the second processor socket interface 126 may be substantially different from each other in some embodiments. For example, the first processor socket interface 116 and the second processor socket interface 126 may be configured for different types of chip substrates, differently shaped chip substrates, differently sized chip substrates, different processing units, different signal connections, and/or the like, which may result in the first processor socket interface 116 and the second processor socket interface 126 having different mechanical and/or electrical characteristics as compared to each other.

As will be appreciated by one of ordinary skill in the art in view of this disclosure, FIGS. 1A-1G depict a simplified and/or representative design for an electronic module 100 and components thereof, in accordance with an embodiment of the invention. For example, the electronic module 100 may include more components (e.g., PCBs, chip substrates, processing units, pins, contacts, sockets, attachment features, attachment members, sockets, socket interfaces, test points, PCB portions, bolts, nuts, and/or the like), fewer components, differently sized, shaped, and/or positioned components, and/or the like. As another example, the electronic module 100, the main PCB 102, the chip substrates 110, 120, the processing units 112, 122, and/or the intermediate PCB 130 may have a different size and/or shape as compared to that shown in FIGS. 1A-1G.

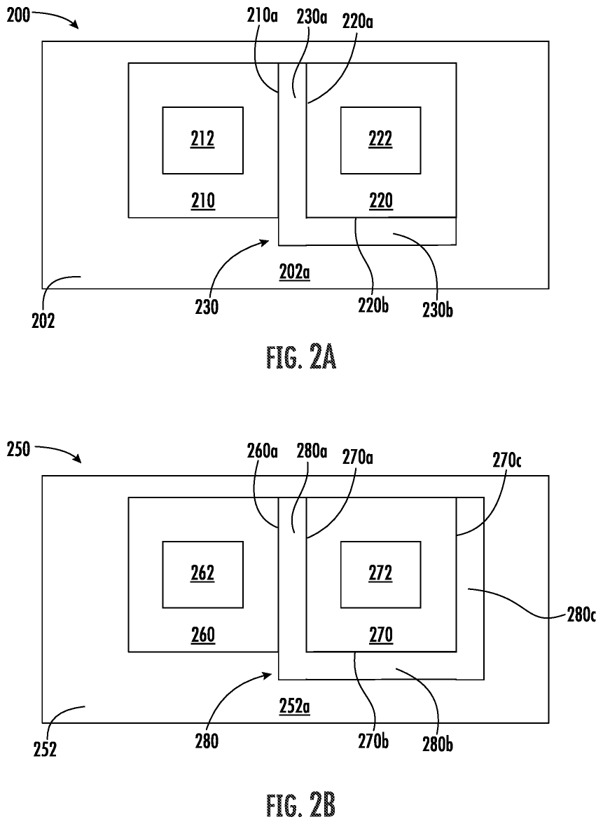

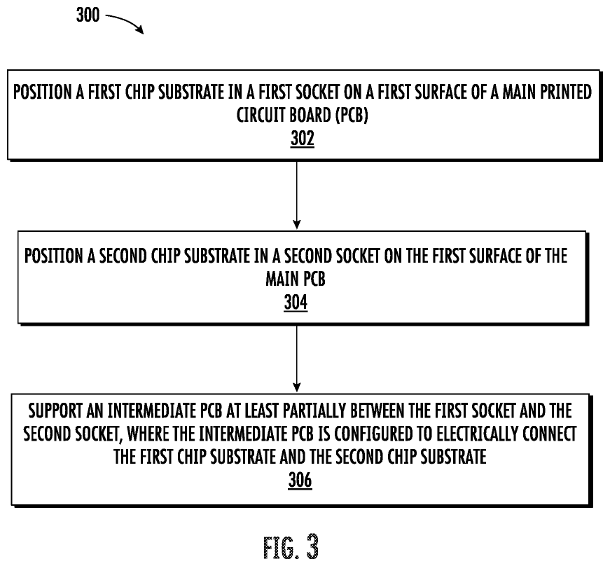

FIG. 2A is a schematic overhead view of an electronic module 200, in accordance with an embodiment of the invention. As shown in FIG. 2A, the electronic module 200 may include a main PCB 202 having a first surface 202a, a first chip substrate 210, a second chip substrate 220, and an intermediate PCB 230. In some embodiments, the electronic module 200 may be similar to the electronic module 100 shown and described herein with respect to FIGS. 1A-1G. For example, the main PCB 202, the first chip substrate 210, the second chip substrate 220, and the intermediate PCB 230 may be similar to the main PCB 102, the first chip substrate 110, the second chip substrate 120, and the intermediate PCB 130 shown and described herein with respect to FIGS. 1A-1G. As another example, the first chip substrate 210 and the second chip substrate 220 may include a first processing unit 212 and a second processing unit 222, respectively, which may be similar to the first processing unit 112 and the second processing unit 122 shown and described herein with respect to FIGS. 1A-1G.

In some embodiments, and as shown in FIG. 2A, the intermediate PCB 230 may include a first portion 230a disposed between a first side 210a of the first chip substrate 210 and a first side 220a of the second chip substrate 220 as well as a second portion extending along a second side 220b of the second chip substrate 220. In such embodiments, the first portion 230a may be electrically connected to the first chip substrate 210 and/or the second chip substrate 220 (e.g., via pins and contacts in a manner similar to that described herein with respect to FIGS. 1A-1G). Additionally, in such embodiments the second portion 230b may be electrically connected to the second side 220b of the second chip substrate 220 (e.g., via pins and contacts in a manner similar to that described herein with respect to FIGS. 1A-1G). In this way, the intermediate PCB 230 may provide a C2C interconnection between the first chip substrate 210 and the second chip substrate 220 via the first sides 210a, 220a of the first chip substrate 210 and the second chip substrate 220 oriented toward the first portion 230a and/or via the second side 220b of the second chip substrate 220 oriented toward the second portion 230b.

As shown in FIG. 2A, the second portion 230b of the intermediate PCB 230 may extend along the second side 220b (e.g., a lower side in the orientation shown in FIG. 2A) of the second chip substrate 220. As will be appreciated by one of ordinary skill in the art in view of the present disclosure, the second portion 230b may extend along another side of the second chip substrate 220 in some embodiments, such as the upper side and/or the right side in the orientation shown in FIG. 2A. Additionally, or alternatively, the second portion 230b may extend along a side of the first chip substrate 210, such as the lower side, the upper side, and/or the right side in the orientation shown in FIG. 2A.

FIG. 2B is a schematic overhead view of an electronic module 250, in accordance with an embodiment of the invention. As shown in FIG. 2B, the electronic module 250 may include a main PCB 252 having a first surface 252a, a first chip substrate 260, a second chip substrate 270, and an intermediate PCB 280. In some embodiments, the electronic module 250 may be similar to the electronic module 100 shown and described herein with respect to FIGS. 1A-1G. For example, the main PCB 252, the first chip substrate 260, the second chip substrate 270, and the intermediate PCB 280 may be similar to the main PCB 102, the first chip substrate 110, the second chip substrate 120, and the intermediate PCB 130 shown and described herein with respect to FIGS. 1A-1G. As another example, the first chip substrate 260 and the second chip substrate 270 may include a first processing unit 262 and a second processing unit 272, respectively, which may be similar to the first processing unit 112 and the second processing unit 122 shown and described herein with respect to FIGS. 1A-1G.

In some embodiments, and as shown in FIG. 2B, the intermediate PCB 230 may include a first portion 280a, a second portion 280b, and a third portion 280c. As shown in FIG. 2B, the first portion 280a may be disposed between a first side 260a of the first chip substrate 260 and a first side 270a of the second chip substrate 270. The second portion 280b may extend along a second side 270b of the second chip substrate 220, and the third portion 280c may extend along a third side 270c of the second chip substrate 220. In such embodiments, the first portion 280a may be electrically connected to the first chip substrate 260 and/or the second chip substrate 270 (e.g., via pins and contacts in a manner similar to that described herein with respect to FIGS. 1A-1G). Additionally, in such embodiments the second portion 280b may be electrically connected to the second side 270b of the second chip substrate 270 (e.g., via pins and contacts in a manner similar to that described herein with respect to FIGS. 1A-1G). Furthermore, in such embodiments the third portion 280c may be electrically connected to the third side 270c of the second chip substrate 270 (e.g., via pins and contacts in a manner similar to that described herein with respect to FIGS. 1A-1G). In this way, the intermediate PCB 280 may provide a C2C interconnection between the first chip substrate 260 and the second chip substrate 270 (i) via the first sides 260a, 270a of the first chip substrate 260 and the second chip substrate 270 oriented toward the first portion 280a, (ii) via the second side 270b of the second chip substrate 270 oriented toward the second portion 280b, and/or (iii) via the third side 270c of the second chip substrate 270 oriented toward the third portion 280c.

As shown in FIG. 2B, the second portion 280b of the intermediate PCB 280 may extend along the second side 270b (e.g., a lower side in the orientation shown in FIG. 2B) of the second chip substrate 270, and the third portion 280c of the intermediate PCB 280 may extend along a third side 270c (e.g., a right side in the orientation shown in FIG. 2B). As will be appreciated by one of ordinary skill in the art in view of the present disclosure, the second portion 280b may extend along another side of the second chip substrate 270 in some embodiments, such as the upper side in the orientation shown in FIG. 2B. Additionally, or alternatively, the second portion 280b may extend along a side of the first chip substrate 260, such as the lower side, the upper side, and/or the right side in the orientation shown in FIG. 2B. In some embodiments, the third portion 280c may extend along a side of the first chip substrate 260, such as the lower side, the upper side, and/or the right side in the orientation shown in FIG. 2B.

As will be appreciated by one of ordinary skill in the art in view of this disclosure, the embodiments of FIGS. 2A and 2B provide increased flexibility with respect to the orientation of the first and second chip substrates on the main PCB. Using FIG. 2A as an example, if the second chip substrate 220 only has contacts on the second side 220b, the intermediate PCB 230 may be configured to have the first portion 230a for electrically connecting to the first side 210a of the first chip substrate 210 and the second portion 230b for electrically connecting to the second side 220b of the second chip substrate 220. Using FIG. 2B as another example, if the second chip substrate 270 only has contacts on the third side 270c, the intermediate PCB 280 may be configured to have the first portion 280a for electrically connecting to the first side 260a of the first chip substrate 260 and the third portion 280c for electrically connecting to the third side 270c of the second chip substrate 270. In this way, the orientation of the first and second chip substrates on the main PCB may be selected to optimize performance, simplify manufacturing, and/or the like, and the intermediate PCB may be configured to provide the appropriate electrical interconnection between the first and second chip substrates.

As will be appreciated by one of ordinary skill in the art in view of this disclosure, FIGS. 2A and 2B depict simplified and/or representative designs for the electronic modules 200, 250 and components thereof, in accordance with embodiments of the invention. For example, the electronic module 200 and/or the electronic module 250 may include more components (e.g., PCBs, chip substrates, processing units, pins, contacts, sockets, attachment features, attachment members, sockets, socket interfaces, test points, PCB portions, bolts, nuts, and/or the like), fewer components, differently sized, shaped, and/or positioned components, and/or the like. As another example, the electronic modules 200, 250, the main PCBs 202, 252, the chip substrates 210, 220, 260, and 270, the processing units 212, 222, and/or the intermediate PCBs 230, 280 may have a different size and/or shape as compared to that shown in FIGS. 2A and 2B.

FIG. 3 is a flowchart illustrating a method 300 of manufacturing an electronic module, in accordance with an embodiment of the invention. In some embodiments, the electronic module may be similar to one or more of the electronic modules described herein, such as the electronic module 100 of FIGS. 1A-1G, the electronic module 200 of FIG. 2A, and/or the electronic module 250 of FIG. 2B.

As shown in block 302, the method 300 may include positioning a first chip substrate in a first socket on a first surface of a main PCB. In some embodiments, the main PCB, the first surface, the first socket, and the first chip substrate may be similar to the main PCB 102, the first surface 102a, the first processor socket 106a, and the first chip substrate 110, respectively, as shown and described herein with respect to FIGS. 1A-1G. Additionally, or alternatively, the main PCB, the first surface, and the first chip substrate may be similar to the main PCB 202, the first surface 202a, and the first chip substrate 210, respectively, as shown and described herein with respect to FIG. 2A. In some embodiments, the main PCB, the first surface, and the first chip substrate may be similar to the main PCB 252, the first surface 252a, and the first chip substrate 260, respectively, as shown and described herein with respect to FIG. 2B.

As shown in block 304, the method 300 may include positioning a second chip substrate in a second socket on the first surface of the main PCB. In some embodiments, the second chip substrate and the second socket may be similar to the second chip substrate 120 and the second processor socket 106b, respectively, as shown and described herein with respect to FIGS. 1A-1G. Additionally, or alternatively, the second chip substrate may be similar to the second chip substrate 220 and/or the second chip substrate 270 as shown and described herein with respect to FIGS. 2A and 2B, respectively.

As shown in block 306, the method 300 may include supporting an intermediate PCB at least partially between the first socket and the second socket, where the intermediate PCB is configured to electrically connect the first chip substrate and the second chip substrate. In some embodiments, the intermediate PCB may be similar to the intermediate PCB 130, the intermediate PCB 230, and/or the intermediate PCB 280 as shown and described herein with respect to FIGS. 1A-1G, 2A, and 2B, respectively.

In some embodiments, the method 300 may include positioning pins of the intermediate PCB in sockets of the first chip substrate and the second chip substrate. Additionally, or alternatively, the method 300 may include electrically connecting the intermediate PCB with the first chip substrate and the second chip substrate via pins of the intermediate PCB and sockets of the first chip substrate and the second chip substrate, respectively. For example, the intermediate PCB may include pins similar to the first pins 132a and the second pins 132b shown and described herein with respect to FIGS. 1A-1E, where the pins extend substantially parallel to the first surface of the main PCB from the intermediate PCB toward the first chip substrate and the second chip substrate.

In some embodiments, the method 300 may include testing an electrical connection via one or more test points on the intermediate PCB. For example, the intermediate PCB may include one or more test points similar to the first test points 136a and the second test points 136b shown and described herein with respect to FIG. 1C, where the one or more test points are accessible when the intermediate PCB is disposed on the first surface of the main PCB between the first chip substrate and the second chip substrate.

Method 300 may include additional embodiments, such as any single embodiment or any combination of embodiments described herein. Although FIG. 3 shows example blocks of method 300, in some embodiments, method 300 may include additional blocks, fewer blocks, different blocks, or differently arranged blocks than those depicted in FIG. 3. Additionally, or alternatively, two or more of the blocks of method 300 may be performed in parallel.

As will be appreciated by one of ordinary skill in the art in view of this disclosure, the present invention may include and/or be embodied as an apparatus (including, for example, a system, a machine, a device, and/or the like), as a method (including, for example, a manufacturing method, a robot-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention, and that this invention is not limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the invention. For example, devices, modules, components, and/or elements shown in the figures are not necessarily drawn to scale and may vary from that shown without departing from the scope and spirit of the invention. Therefore, it is to be understood that, within the scope of the appended claims, the invention may be practiced other than as specifically described herein.

What is claimed is:

1. An electronic module, comprising:
a main printed circuit board (PCB) having a first surface;
a first chip substrate disposed on the first surface of the main PCB;
a second chip substrate disposed on the first surface of the main PCB; and
an intermediate PCB supported by the main PCB, wherein at least a portion of the intermediate PCB is disposed between the first chip substrate and the second chip substrate, and wherein the intermediate PCB electrically connects the first chip substrate to the second chip substrate.

2. The electronic module of claim 1, wherein the intermediate PCB comprises:
first pins extending substantially parallel to the first surface of the main PCB from the intermediate PCB toward the first chip substrate; and
second pins extending substantially parallel to the first surface of the main PCB from the intermediate PCB toward the second chip substrate,
wherein the first pins and the second pins are configured to electrically connect to the first chip substrate and the second chip substrate, respectively.

3. The electronic module of claim 2, wherein:
the first chip substrate comprises first contacts oriented toward the intermediate PCB, wherein each first contact is configured to electrically connect to a corresponding first pin of the first pins; and
the second chip substrate comprises second contacts oriented toward the intermediate PCB, wherein each second contact is configured to electrically connect to a corresponding second pin of the second pins.

4. The electronic module of claim 3, wherein:
the first contacts are disposed on a first chip surface of the first chip substrate that is substantially perpendicular to the first surface of the main PCB; and
the second contacts are disposed on a second chip surface of the second chip substrate that is substantially perpendicular to the first surface of the main PCB.

5. The electronic module of claim 3, wherein the first chip substrate defines a first socket, the first socket comprising the first contacts, and wherein the second chip substrate defines a second socket, the second socket comprising the second contacts.

6. The electronic module of claim 3, wherein the first surface of the main PCB defines a first processor socket and a second processor socket;
wherein the first chip substrate comprises a first processor socket interface configured to electrically connect to the first processor socket, and wherein the first contacts and the first processor socket interface are on different surfaces of the first chip substrate; and
wherein the second chip substrate comprises a second processor socket interface configured to electrically connect to the second processor socket, and wherein the second contacts and the second processor socket interface are on different surfaces of the second chip substrate.

7. The electronic module of claim 2, wherein the intermediate PCB comprises:
first test points configured to allow testing of first electrical connections between the first pins and the intermediate PCB, wherein each first test point corresponds to a first pin of the first pins; and
second test points configured to allow testing of second electrical connections between the second pins and the intermediate PCB, wherein each second test point corresponds to a second pin of the second pins.

8. The electronic module of claim 1, wherein the intermediate PCB comprises:
a first portion disposed between a first side of the first chip substrate and a first side of the second chip substrate; and
a second portion extending along a second side of one of the first chip substrate or the second chip substrate.

9. The electronic module of claim 8, wherein:
the first portion is electrically connected to one of the first chip substrate or the second chip substrate; and
the second portion is electrically connected to the second side of the one of the first chip substrate or the second chip substrate.

10. The electronic module of claim 8, wherein the intermediate PCB comprises a third portion extending along a third side of the one of the first chip substrate or the second chip substrate.

11. The electronic module of claim 10, wherein:
the first portion is electrically connected to one of the first chip substrate or the second chip substrate; and
the third portion is electrically connected to the third side of the one of the first chip substrate or the second chip substrate.

12. The electronic module of claim 1, wherein the intermediate PCB comprises:
a first attachment feature configured to secure a first end of the intermediate PCB to the main PCB; and
a second attachment feature configured to secure a second end of the intermediate PCB to the main PCB.

13. The electronic module of claim 12, wherein:
the first attachment feature comprises a first opening extending through the intermediate PCB, wherein the main PCB defines a first corresponding opening extending from the first surface to a second surface of the main PCB; and
the second attachment feature comprises a second opening extending through the intermediate PCB, wherein the main PCB defines a second corresponding opening extending from the first surface to a second surface of the main PCB,
wherein the first attachment feature and the first corresponding opening of the main PCB are configured to receive a first attachment member therethrough, and
wherein the second attachment feature and the second corresponding opening of the main PCB are configured to receive a second attachment member therethrough.

14. The electronic module of claim 13, wherein the first attachment member comprises a first bolt, and wherein the second attachment member comprises a second bolt.

15. The electronic module of claim 1, wherein the first chip substrate comprises a first processing unit, and the second chip substrate comprises a second processing unit.

16. The electronic module of claim 15, wherein, in an operable configuration, the first processing unit and the second processing unit are configured to communicate with each other via an electrical connection provided by the intermediate PCB.

17. The electronic module of claim 16, wherein, in an operable configuration, the first processing unit and the second processing unit communicate with each other only via the electrical connection provided by the intermediate PCB, the first chip substrate, and the second chip substrate.

18. A method of manufacturing an electronic module, the method comprising:
positioning a first chip substrate in a first socket on a first surface of a main printed circuit board (PCB);
positioning a second chip substrate in a second socket on the first surface of the main PCB; and
supporting an intermediate PCB at least partially between the first socket and the second socket, wherein the intermediate PCB is configured to electrically connect the first chip substrate and the second chip substrate.

19. The method of claim 18, comprising electrically connecting the intermediate PCB with the first chip substrate and the second chip substrate via pins of the intermediate PCB and sockets of the first chip substrate and the second chip substrate, respectively.

20. The method of claim 18, comprising testing an electrical connection via one or more test points on the intermediate PCB.
